(19) United States
(12) Patent Application Publication
(10) Pub. No.: US 2026/0053034 A1
(43) Pub. Date: Feb. 19, 2026

(54) SEMICONDUCTOR PACKAGE INCLUDING GLASS SUBSTRATE

(71) Applicant: Samsung Electronics Co., Ltd., Suwon-si (KR)

(72) Inventor: Junghwan PARK, Suwon-si (KR)

(73) Assignee: Samsung Electronics Co., Ltd., Suwon-si (KR)

(21) Appl. No.: 19/257,619

(22) Filed: Jul. 2, 2025

(30) Foreign Application Priority Data
Aug. 19, 2024 (KR) 10-2024-0110307

(51) Int. Cl. H01L 23/15; H01L 23/31; H01L 23/538

(52) U.S. Cl. CPC H01L 23/15; H01L 23/3107; H01L 23/538; H01L 23/5384

(57) ABSTRACT

A semiconductor package includes a glass substrate including a glass core and through-vias, an upper redistribution structure including a plurality of upper redistribution layers disposed on the glass substrate and electrically connected to the through-vias, a first chip structure and a second chip structure disposed on the upper redistribution structure and electrically connected to the upper redistribution structure, an encapsulant at least partially covering the first chip structure and the second chip structure, a lower redistribution structure disposed below the glass substrate and including at least one lower redistribution layer electrically connected to the through-vias, and an interconnection chip disposed below the lower redistribution structure and electrically connecting the first chip structure to the second chip structure.

### CROSS-REFERENCE TO RELATED APPLICATION(S)

This U.S. non-provisional application claims priority under 35 U.S.C. § 119 to Korean Patent Application No. 10-2024-0110307 filed on Aug. 19, 2024, in the Korean Intellectual Property Office, the disclosure of which is incorporated herein by reference in its entirety.

### BACKGROUND

Some example embodiments of the inventive concepts relate to a semiconductor package including a glass substrate.

As demand for increased performance, increased speed, and/or multifunctional capabilities of semiconductor devices has increased, the integration of semiconductor devices has also increased. In manufacturing high integration semiconductor devices with smaller patterns, it is beneficial to implement patterns having a decreased width and/or a decreased spacing. Accordingly, a size or thickness of a substrate on which semiconductor chips are mounted has reduced. It is beneficial to reduce damage and/or warpage of the substrates during a semiconductor package manufacturing process.

### SUMMARY

Some example embodiments of the inventive concepts provide a semiconductor package including a glass substrate.

According to some example embodiments of the inventive concepts, a semiconductor package includes a glass substrate including a glass core and through-vias, an upper redistribution structure including a plurality of upper redistribution layers disposed on the glass substrate and electrically connected to the through-vias, a first chip structure and a second chip structure disposed on the upper redistribution structure and electrically connected to the upper redistribution structure, an encapsulant at least partially covering the first chip structure and the second chip structure, a lower redistribution structure disposed below the glass substrate and including at least one lower redistribution layer electrically connected to the through-vias, and an interconnection chip disposed below the lower redistribution structure and electrically connecting the first chip structure to the second chip structure.

According to some example embodiments of the inventive concepts, a semiconductor package includes an interposer structure, a first chip structure and a second chip structure disposed on the interposer structure, an interconnection chip disposed below the interposer structure and electrically connecting the first chip structure to the second chip structure, and an adhesive layer between the interposer structure and the interconnection chip. The interposer structure includes a glass substrate including a glass core and through-vias, an upper redistribution structure disposed on the glass substrate and including a plurality of upper redistribution layers electrically connected to the through-vias, and a lower redistribution structure disposed below the glass substrate and including a plurality of lower redistribution layers electrically connected to the through-vias. A thickness of the upper redistribution structure is greater than a thickness of the lower redistribution structure.

According some example embodiments of the inventive concepts, a semiconductor package includes a glass substrate including a glass core and through-vias, an upper redistribution structure disposed on the glass substrate and including upper redistribution layers electrically connected to the through-vias and upper redistribution vias connecting the upper redistribution layers, a first chip structure and a second chip structure disposed on the upper redistribution structure and electrically connected to the upper redistribution structure, an encapsulant at least partially covering the first chip structure and the second chip structure, a lower redistribution structure disposed below the glass substrate and including a plurality of lower redistribution layers electrically connected to the through-vias and lower redistribution vias connecting the plurality of lower redistribution layers, an interconnection chip disposed below the lower redistribution structure and electrically connecting the first chip structure to the second chip structure, an interconnection terminal between the interconnection chip and the lower redistribution structure, and an adhesive layer disposed between the interconnection chip and the lower redistribution structure and at least partially covering the interconnection terminal.

### BRIEF DESCRIPTION OF DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package, according to some example embodiments.

FIG. 2 is a vertical cross-sectional view of the semiconductor package illustrated in FIG. 1, taken along line I-I′.

FIG. 3 is a partially enlarged view of the semiconductor package illustrated in FIG. 2.

FIG. 4A is a vertical cross-sectional view of a semiconductor package, according to some example embodiments.

FIGS. 4B, 4C, and 4D are partially enlarged views of portion C of the semiconductor package in FIG. 4A, according to some example embodiments.

FIGS. 5 and 6 are vertical cross-sectional views of semiconductor packages, according to some example embodiments.

FIGS. 7, 8, 9, 10, and 11 are views illustrating a method for manufacturing a semiconductor package, according to some example embodiments.

### DETAILED DESCRIPTION

Hereinafter, example embodiments of the inventive concepts will be described with reference to the accompanying drawings.

In the drawings, the thickness of layers, films, panels, regions, etc., are exaggerated for clarity.

In the drawings, parts having no relationship with the description are omitted for clarity, and the same or similar constituent elements are indicated by the same reference numeral throughout the specification.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

Hereinafter, the terms “lower portion” and “upper portion” are for convenience of description and do not limit the positional relationship.

As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C,” “at least one of A, B, or C”) may be construed as A only, B only, C only, or any combination of two or more of A, B, and C, such as, for instance, ABC, AB, BC, and AC.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element, value, and/or property is referred to as being the same as another element, value, and/or property, it should be understood that an element, value, and/or property is the same as another element, value, and/or property within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

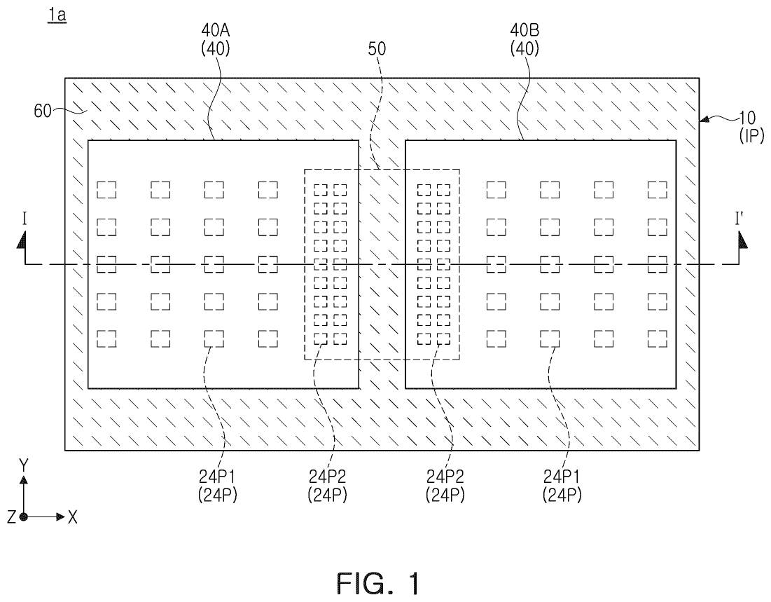

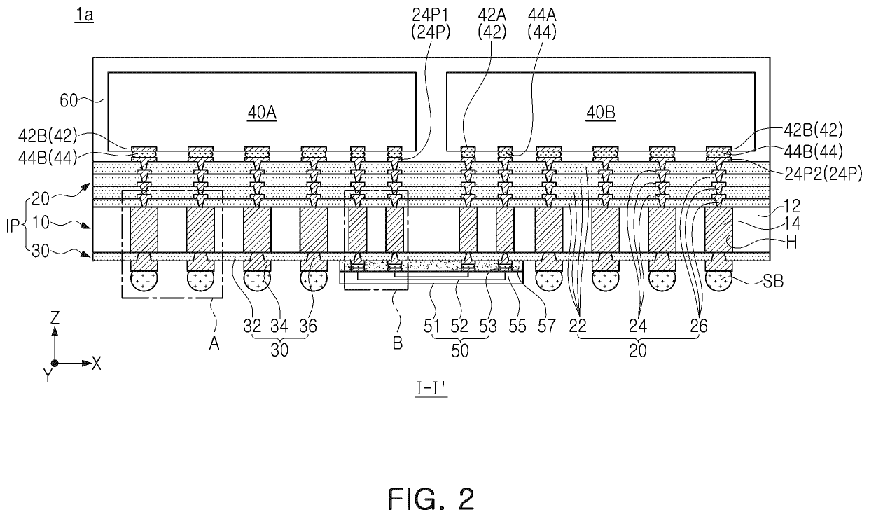

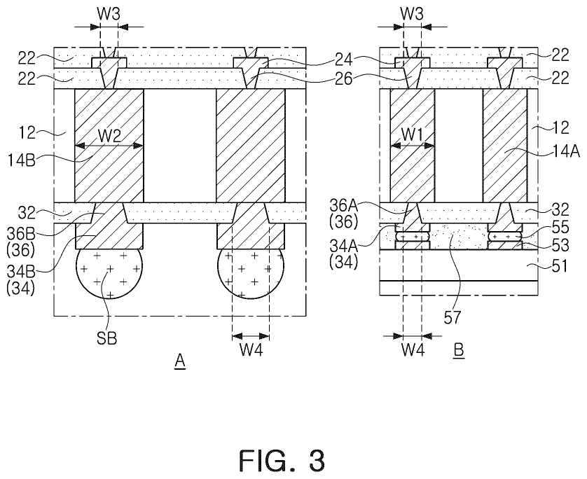

FIG. 1 is a plan view of a semiconductor package, according to some example embodiments. FIG. 2 is a vertical cross-sectional view of the semiconductor package illustrated in FIG. 1, taken along line I-I′. FIG. 3 illustrates partially enlarged views of portions A and B of the semiconductor package illustrated in FIG. 2.

Referring to FIGS. 1 to 3, a semiconductor package 1a, according to some example embodiments, may include an interposer structure IP, a chip structure 40, an interconnection chip 50, an encapsulant 60, and a solder bump SB. The interposer structure IP may include a glass substrate 10 (or an ‘interposer substrate’), an upper redistribution structure 20, and a lower redistribution structure 30.

In some example embodiments, the glass substrate 10 may include a glass core 12 and a through-via 14. The glass core 12 may include a through-hole H. The through-hole H may penetrate the glass core 12 in a vertical direction (a Z-direction). The through-hole H may have, for example, a cylindrical shape, but is not limited thereto.

The glass core 12 may be or include, for example, glass. The coefficient of thermal expansion (CTE) of the glass core 12 is relatively lower than that of a thermosetting resin or a photosensitive insulating layer, so that warpage of the semiconductor package 1a may be limited, reduced, or minimized.

The through-via 14 may be disposed within the through-hole H. For example, the through-via 14 may completely fill the through-hole H. The through-via 14 may be cylindrical, but is not limited thereto. An upper surface and a lower surface of the through-via 14 may be coplanar with an upper surface and a lower surface of the glass core 12, respectively. In some example embodiments, horizontal widths W1 and W2 of the through-via 14 may be in the range of 1 μm (or about 1 μm) to 200 μm (or about 200 μm). The pitch of the through-via 14 may be in the range of 10 μm (or about 10 μm) to 100 μm (or about 100 μm).

The through-via 14 may be or include a conductive material. The through-via 14 may include a metallic material including, for example, copper (Cu), aluminum (Al), silver (Ag), tin (Sn), gold (Au), nickel (Ni), lead (Pb), titanium (Ti), or alloys thereof.

The upper redistribution structure 20 may be disposed on the glass substrate 10. The upper redistribution structure 20 may include an upper insulating layer 22, an upper redistribution layer 24, and an upper redistribution via 26.

The upper insulating layer 22 may be or include a thermosetting resin, such as an epoxy resin, a thermoplastic resin, such as a polyimide, or a resin impregnated with an inorganic filler in these resins, for example, a photosensitive resin, such as a prepreg, Ajinomoto build-up film (ABF), FR-4, bismaleimide triazine (BT), or photo imageable dielectric (PID) resin. The upper insulating layer 22 may be formed of a plurality of layers, and the boundaries between adjacent or adjoining layers may be observed. However, depending on the process, in some example embodiments, the boundaries between adjacent or adjoining layer may merge with each other and may not be noticeable.

The upper redistribution layer 24 may be disposed on or within the upper insulating layer 22 and may be formed of a plurality of layers. The upper redistribution via 26 may interconnect upper redistribution layers 24 disposed on different layers. A horizontal width W3 of the upper redistribution via 26 may be less than the horizontal widths W1 and W2 of the through-via 14. For example, a difference between the horizontal width W3 of the upper redistribution via 26 and the horizontal widths W1 and W2 of the through-via 14 may be in a range of 5 μm (or about 5 μm) to 50 μm (or about 50 μm). The upper redistribution structure 20 may be electrically connected to the glass substrate 10 and the chip structure 40. For example, the upper redistribution layer 24 and the upper redistribution via 26 may electrically connect the interconnection chip 50 and the glass substrate 10. The upper redistribution layer 24 may substantially redistribute the through-via 14 of the glass substrate 10. The upper redistribution layer 24 may be or include, for example, a metallic material including copper (Cu), aluminum (Al), silver (Ag), tin (Sn), gold (Au), nickel (Ni), lead (Pb), titanium (Ti), or alloys thereof. The upper redistribution layer 24 may be or include a ground (GND) pattern, a power (PWR) pattern, and a signal(S) pattern depending on application and/or design. The signal(S) pattern may provide a transmission path for various signals excluding the ground GND pattern, the power PWR pattern, and the like.

The lower redistribution structure 30 may be disposed below the glass substrate 10. The lower redistribution structure 30 may include a lower insulating layer 32, a lower redistribution layer 34 (or a ‘lower pad’), and a lower redistribution via 36.

The lower insulating layer 32 may be or include a thermosetting resin, such as an epoxy resin, a thermoplastic resin, such as a polyimide, or a resin impregnated with an inorganic filler in these resins, for example, a photosensitive resin, such as a prepreg, ABF, FR-4, BT, or PID resin. The lower insulating layer 32 may be formed of a plurality of layers, and the boundaries of adjacent or adjoining layers may be noticeable. However, in some example embodiments, the boundaries between adjacent or adjoining layers may merge and may not be noticeable. In some example embodiments, a number of the lower insulating layers 32 and the upper insulating layers 22 may be different.

The lower redistribution layer 34 may be disposed on or within the lower insulating layer 32. The lower redistribution via 36 may connect the lower redistribution layer 34 to the glass substrate 10. The lower redistribution structure 30 may be electrically connected to the glass substrate 10 and the interconnection chip 50. For example, the lower redistribution layer 34 and the lower redistribution via 36 may electrically connect the interconnection chip 50 and the glass substrate 10. The lower redistribution layer 34 may substantially redistribute the through-via 14 of the glass substrate 10. The lower redistribution layer 34 may be or include a metallic material including, for example, copper (Cu), aluminum (Al), silver (Ag), tin (Sn), gold (Au), nickel (Ni), lead (Pb), titanium (Ti), or alloys thereof. The lower redistribution layer 34 may include a ground GND pattern, a power (PWR) pattern, and a signal(S) pattern depending on application and/or design. The signal(S) pattern may provide a transmission path for various signals excluding the ground GND pattern and power PWR pattern and the like.

The solder bump SB may be disposed below the lower redistribution structure 30. For example, the solder bump SB may be in contact with the lower redistribution layer 34. The lower redistribution layer 34 may include a line pattern extending in a horizontal direction and a pad pattern connected to the line pattern, and the solder bump SB may be connected to the pad pattern of the lower redistribution layer 34. The solder bump SB may be or include, for example, tin (Sn), indium (In), bismuth (Bi), antimony SB, copper (Cu), silver (Ag), zinc (Zn), lead (Pb), or alloys thereof (for example, Sn—Ag—Cu).

The upper redistribution structure 20 may further include pad structures 24P disposed on the uppermost of the upper insulating layers 22. The pad structures 24P may electrically connect the chip structures 40 and the upper redistribution layer 24. The pad structures 24P may include first pad structures 24P1 and second pad structures 24P2. The first pad structures 24P1 may vertically overlap the interconnection chip 50 and may be electrically connected to the interconnection chip 50 through the upper redistribution layer 24 and the glass substrate 10. The second pad structures 24P2 may not vertically overlap the interconnection chip 50 (e.g., may be horizontally offset from the interconnection chip 50) and may be electrically connected to the glass substrate 10 through the upper redistribution layer 24.

In some example embodiments, the pitch of the first pad structures 24P1 may be less than the pitch of the second pad structures 24P2. Here, the pitch of the first pad structures 24P1 and the pitch of the second pad structures 24P2 may refer to a horizontal distance (or separation) between the centers of the first pad structures 24P1 and a horizontal distance between the centers of the second pad structures 24P2, respectively. Although the horizontal width of the first pad structures 24P1 and the horizontal width of the second pad structures 24P2 are shown to be different, they are not limited thereto. In some example embodiments, the horizontal width of the first pad structures 24P1 and the horizontal width of the second pad structures 24P2 may be substantially the same.

The chip structures 40 may be mounted on the upper redistribution structure 20. The chip structures 40 may be electrically connected to the upper redistribution structure 20. For example, the semiconductor package 1a may further include chip connection terminals 44 disposed between the chip structures 40 and the upper redistribution structure 20. The chip connection terminals 44 may be in contact with chip pads 42 disposed on a lower surface of the chip structures 40. The chip pads 42 may electrically connect the chip structures 40 and the upper redistribution structure 20.

The chip pads 42 may include first chip pads 42A and second chip pads 42B. The first chip pads 42A may vertically overlap the interconnection chip 50, and the second chip pads 42B may not vertically overlap the interconnection chip 50 (for example, may be offset in the horizontal direction from the interconnection chip 50). The chip connection terminals 44 may include first chip connection terminals 44A and second chip connection terminals 44B. The first chip connection terminals 44A may vertically overlap the interconnection chip 50, and the second chip connection terminals 44B may not vertically overlap the interconnection chip 50 (for example, may be horizontally offset from the interconnection chip 50). For example, the first chip pads 42A may be electrically connected to the first pad structures 24P1 through the first chip connection terminals 44A. The second chip pads 42B may be electrically connected to the second pad structures 24P2 through the second chip connection terminals 44B. In some example embodiments, the pitch of the first chip pads 42A may be less than the pitch of the second chip pads 42B. In some example embodiments, the pitch of the first chip connection terminals 44A may be less than the pitch of the second chip connection terminals 44B.

The chip pads 42 may be or include, for example, a metallic material including copper (Cu), aluminum (Al), silver (Ag), tin (Sn), gold (Au), nickel (Ni), lead (Pb), titanium (Ti), or alloys thereof. The chip connection terminals 44 may be or include, for example, tin (Sn), indium (In), bismuth (Bi), antimony SB, copper (Cu), silver (Ag), zinc (Zn), lead (Pb), or alloys thereof (e.g., Sn—Ag—Cu).

The chip structures 40 may be electrically connected to at least one of the glass substrate 10, the lower redistribution structure 30, and/or the interconnection chip 50 through the upper redistribution structure 20. In some example embodiments, the chip structures 40 may be electrically connected to each other by the first pad structures 24P1, the upper redistribution structure 20, the glass substrate 10, and the interconnection chip 50.

Each of the chip structures 40 may overlap at least a portion of the interconnection chip 50 in a direction (the Z-direction), perpendicular to the interposer structure IP. For example, the chip structures 40 may include a first chip structure 40A and a second chip structure 40B that are disposed on the upper surface of the upper redistribution structure 20 and overlap at least portions of the interconnection chip 50, respectively.

The first chip structure 40A and the second chip structure 40B may include a logic chip (or a processor chip), such as a central processing unit (CPU), a graphics processing unit (GPU), a field programmable gate array (FPGA), an application processor (AP), a digital signal processor, an encryption processor, a microprocessor, a microcontroller, an analog-to-digital converter, an application-specific IC (ASIC), and a memory chip including a volatile memory, such as a dynamic RAM (DRAM), a static RAM (SRAM), etc. and a nonvolatile memory, such as a phase change RAM (PRAM), a magnetic RAM (MRAM), a resistive RAM (RRAM), and a flash memory.

According to some example embodiments, the first chip structure 40A and the second chip structure 40B may include different types of semiconductor chips. For example, the first chip structure 40A may include a logic chip, such as a CPU, a GPU, an ASIC, and the second chip structure 40B may include a memory chip, such as a DRAM, a flash memory, and the like.

The interconnection chip 50 may be disposed below the lower redistribution structure 30. A lower surface of the interconnection chip 50 may be disposed on a level higher than a lower end of the solder bump SB. The interconnection chip 50 may include a chip body 51, an interconnection circuit 52, and an interconnection pad 53. The interconnection chip 50 may have a size or horizontal area such that a portion of the chip body 51 may overlap the chip structures 40 in the vertical direction (the Z-direction) to connect the chip structures 40.

The chip body 51 may be formed based on ceramic, glass, a semiconductor, or the like. For example, the chip body 51 may be formed based on an active wafer and may include silicon (Si), germanium (Ge), gallium arsenide (GaAs), or the like. A passivation layer may be formed on one surface of the chip body 51 to protect the chip body 51 from external physical and/or chemical damage. The passivation layer may be formed of an oxide film or a nitride film, or may be formed of a double layer of an oxide film and a nitride film. For example, the passivation layer may be formed of a silicon oxide film (SiO) or a silicon nitride film (SiN), or combinations thereof.

The interconnection circuit 52 may be formed within an interlayer insulating layer formed on one surface of the chip body 51. The interconnection circuit 52 may be electrically connected to the lower redistribution layer 34 and the lower redistribution via 36 through the interconnection pad 53 and may electrically connect the chip structures 40 to each other.

The semiconductor package 1a may further include an interconnection terminal 55 and an adhesive layer 57 between the interconnection chip 50 and the lower redistribution structure 30. In some example embodiments, the interconnection chip 50 may be mounted on the lower redistribution structure 30 in a flip-chip manner. The interconnection terminal 55 may be disposed between the lower redistribution layer 34 and the interconnection pad 53. The interconnection terminal 55 may be or include, for example, tin (Sn), indium (In), bismuth (Bi), antimony SB, copper (Cu), silver (Ag), zinc (Zn), lead (Pb), or alloys thereof (for example, Sn—Ag—Cu).

The adhesive layer 57 may fill a space between the lower surface of the lower redistribution structure 30 and the upper surface of the chip body 51 and may cover or enclose (at least partially) the lower redistribution layers 34, the interconnection pads 53, and the interconnection terminals 55. The adhesive layer 57 may be or include, for example, a die attach film (DAF).

In some example embodiments, the through-via 14 may include a first through-via 14A and a second through-via 14B. The first through-via 14A may vertically overlap the interconnection chip 50, and the second through-via 14B may not vertically overlap the interconnection chip 50 (e.g., may be horizontally offset from the interconnection chip 50). In some example embodiments, the horizontal width W1 of the first through-via 14A may be less than the horizontal width W2 of the second through-via 14B. In some example embodiments, the pitch of the first through-vias 14A may be less than the pitch of the second through-vias 14B. Here, the pitch of the first through-vias 14A and the pitch of the second through-vias 14B may refer to the horizontal distance (or separation) between the centers of the first through-vias 14A and the horizontal distance between the centers of the second through-vias 14B, respectively.

The lower redistribution layer 34 may include a first lower redistribution layer 34A and a second lower redistribution layer 34B. The first lower redistribution layer 34A may vertically overlap the interconnection chip 50, and the second lower redistribution layer 34B may not vertically overlap the interconnection chip 50 (e.g., may be horizontally offset from the interconnection chip 50). The sizes (e.g., widths, lengths, thicknesses, or cross-sectional areas) of the first lower redistribution layer 34A and the second lower redistribution layer 34B may be different from each other (for example, as illustrated in FIG. 3), but are not limited thereto. In some example embodiments, the first lower redistribution layer 34A and the second lower redistribution layer 34B may have substantially the same size.

The lower redistribution via 36 may include a first lower redistribution via 36A and a second lower redistribution via 36B. The first lower redistribution via 36A may vertically overlap the interconnection chip 50, and the second lower redistribution via 36B may not vertically overlap the interconnection chip 50 (e.g., may be horizontally offset from the interconnection chip 50). A horizontal width W4 of the lower redistribution via 36 may be less than the horizontal widths W1 and W2 of the through-via 14. For example, the horizontal width W4 of the first lower redistribution via 36A may be less than the horizontal width W1 of the first through-via 14A, and the horizontal width W4 of the second lower redistribution via 36B may be less than the horizontal width W2 of the second through-via 14B. The horizontal width W4 of the first lower redistribution via 36A is illustrated in FIG. 3 as being different from (e.g., more than) the horizontal width W4 of the second lower redistribution via 36B, but is not limited thereto. In some example embodiments, the horizontal width W4 of the first lower redistribution via 36A may be same as the horizontal width W4 of the second lower redistribution via 36B, and widths of the first lower redistribution via 36A and the second lower redistribution via 36B may be less than the horizontal width W1 of the first through-via 14A and less than the horizontal width W2 of the second through-via 14B.

In some example embodiments, the interconnection chip 50 may be electrically connected to the first through-via 14A, the first lower redistribution layer 34A, and the first lower redistribution via 36A. The interconnection chip 50 may be electrically connected to the chip structures 40 through the first through-vias 14A and the upper redistribution structure 20.

The encapsulant 60 may cover the upper redistribution structure 20 and the chip structures 40. Although the encapsulant 60 is illustrated as completely covering the upper surfaces of the chip structures 40, example embodiments of the inventive concepts are not limited thereto. In some example embodiments, the encapsulant 60 may cover side surfaces of the chip structures 40, and an upper surface of the encapsulant 60 may be coplanar with upper surfaces of the chip structures 40. The encapsulant 60 may be a resin including epoxy or polyimide. For example, the resin may include a bisphenol-group epoxy resin, a polycyclic aromatic epoxy resin, an o-cresol novolac epoxy resin, a biphenyl-group epoxy resin, or a naphthalene-group epoxy resin.

According to some example embodiments, the glass core 12 of the glass substrate 10 may include glass. As described above, the coefficient of thermal expansion of the glass core 12 is relatively lower than that of a thermosetting resin, a thermoplastic resin, or a photosensitive insulating layer, so that warpage of the semiconductor package 1a may be limited, reduced, or minimized. In some example embodiments, the coefficient of thermal expansion of the glass substrate 10 may be higher than that of the chip structures 40. In some example embodiments, the coefficient of thermal expansion of the glass substrate 10 may be less than the coefficient of thermal expansion of the upper redistribution structure 20 and less than the coefficient of thermal expansion of the lower redistribution structure 30. In some example embodiments, the coefficient of thermal expansion of the glass substrate 10 may be in a range of 8 ppm/K (or about 8 ppm/K) to 10 ppm/K (or about 10 ppm/K). In some example embodiments, the thickness of the glass substrate 10 may be in a range of 10 μm (to about 10 μm) to 500 μm (to about 500 μm).

Since the coefficient of thermal expansion of the glass substrate 10 is less than the coefficients of thermal expansion of the upper redistribution structure 20 and the lower redistribution structure 30, even if the upper redistribution structure 20 and the lower redistribution structure 30 are formed asymmetrically, warpage of the interposer structure IP and the semiconductor package 1a may be limited or minimized. For example, the number of upper insulating layers 22 of the upper redistribution structure 20 may be different from the number of lower insulating layers 32 of the lower redistribution structure 30. In some example embodiments, the number of upper insulating layers 22 of the upper redistribution structure 20 may be higher than the number of lower insulating layers 32 of the lower redistribution structure 30. The thickness of the upper redistribution structure 20 may be greater than the thickness of the lower redistribution structure 30.

In addition, since the coefficient of thermal expansion of the glass substrate 10 is relatively small, the glass substrate 10 may be formed to have a large area. For example, the horizontal widths of the glass substrate 10 may be 30 mm (or about 30 mm) and 200 mm (or about 200 mm), respectively. In some example embodiments, the horizontal width of the glass substrate 10 may be the same as the horizontal width of the semiconductor package 1a. For example, the horizontal width of the glass substrate 10 may be equal to the horizontal width of the upper redistribution structure 20, the horizontal width of the lower redistribution structure 30, and/or the horizontal width of the encapsulant 60. The glass substrate 10 may include a first side surface, perpendicular to an X-direction (or a Y-direction), and a second side surface, opposite to the first side surface, and both the first side surface and the second side surface may be coplanar with the upper redistribution structure 20, the lower redistribution structure 30, and the encapsulant 60.

According to some example embodiments, the interconnection chip 50 may not be disposed within the glass substrate 10, the upper redistribution structure 20, or the lower redistribution structure 30. For example, the interconnection chip 50 may be mounted below the lower redistribution structure 30. Therefore, the manufacturing process of the semiconductor package 1a may be relatively simplified and the manufacturing costs may be reduced.

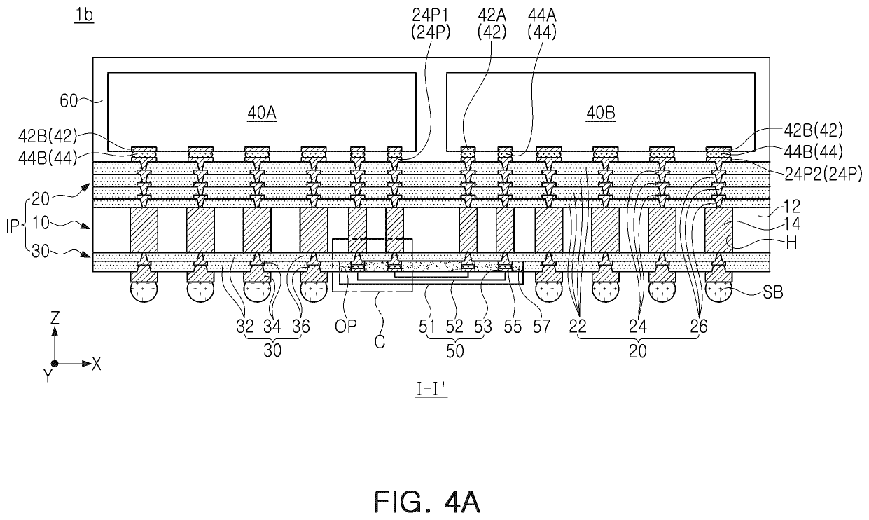

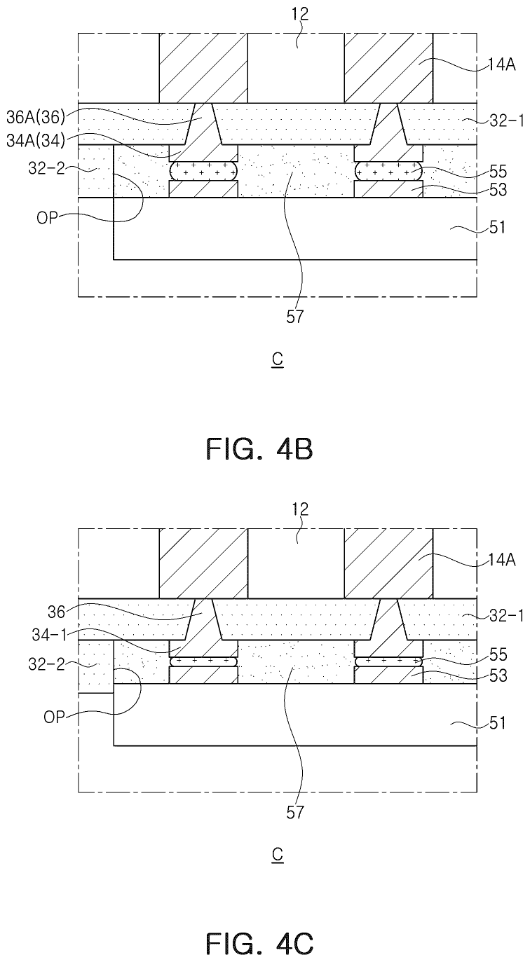

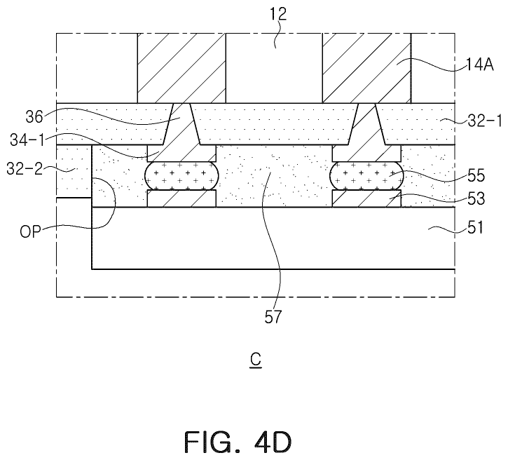

FIG. 4A is a vertical cross-sectional view of a semiconductor package, according to some example embodiments. FIG. 4B is a partially enlarged view of portion C of the semiconductor package in FIG. 4A.

Referring to FIGS. 4A and 4B, a semiconductor package 1b may include a lower redistribution structure 30 and an interconnection chip 50 disposed below the glass substrate 10. In some example embodiments, the lower redistribution structure 30 may include a plurality of lower insulating layers 32 (2 layers shown in FIG. 4A) being vertically stacked, a plurality of lower redistribution layers 34 (2 layers shown in FIG. 4A), and a plurality of lower redistribution vias 36 (2 vias shown in FIG. 4A) connecting the plurality of lower redistribution layers 34. In some example embodiments, the lowermost lower insulating layer 32 among the plurality of lower insulating layers 32 may include an opening OP (or recess). For example, referring to FIG. 4B, the second lower insulating layer 32-2 may be disposed below the first lower insulating layer 32-1, and the second lower insulating layer 32-2 may include the opening OP. The area (e.g., cross-sectional area) of the second lower insulating layer 32-2 may be less than the area (e.g., cross-sectional area) of the first lower insulating layer 32-1. The lower surface of the second lower insulating layer 32-2 may be disposed on a level lower than that of the upper surface of the interconnection pad 53.

The opening OP may expose the first lower insulating layer 32-1 and the first lower redistribution layer 34-1. The adhesive layer 57 may fill at least a portion of the opening OP. The thickness of the adhesive layer 57 is illustrated as being equal to the thickness of the lower insulating layer 32-2 but example embodiments are not limited thereto. The interconnection chip 50 may be disposed in the opening OP. For example, at least a portion of the chip body 51 or at least a portion of the interconnection pad 53 may be disposed within the opening OP.

FIGS. 4C and 4D are partially enlarged views of portion C of the semiconductor package in FIG. 4A, according to some example embodiments.

Referring to FIG. 4C, the semiconductor package may have the same or similar structure in some respects as the example embodiment of FIG. 4B, and may be best understood with reference thereto where like numerals indicate like elements not described again in detail. As shown in FIG. 4C, in some example embodiments, a portion of the chip body 51 may be disposed within the opening OP. For example, the upper surface of the chip body 51 may be disposed on a level higher than that of the lower surface of the lowermost lower insulating layer 32-2 among the plurality of lower insulating layers 32. At least a portion of the chip body 51 may overlap the lowermost lower insulating layer 32-2 in a horizontal direction.

Referring to FIG. 4D, the semiconductor package may have the same or similar structure in some respects as the example embodiment of FIG. 4B, and may be best understood with reference thereto where like numerals indicate like elements not described again in detail. As shown in FIG. 4D, in some example embodiments, the thickness of the adhesive layer 57 may be greater than the height of the opening OP. For example, the lower surface of the adhesive layer 57 and the upper surface of the chip body 51 may be disposed on a level lower than that of the lower surface of the lowermost lower insulating layer 32-2 among the plurality of lower insulating layers 32.

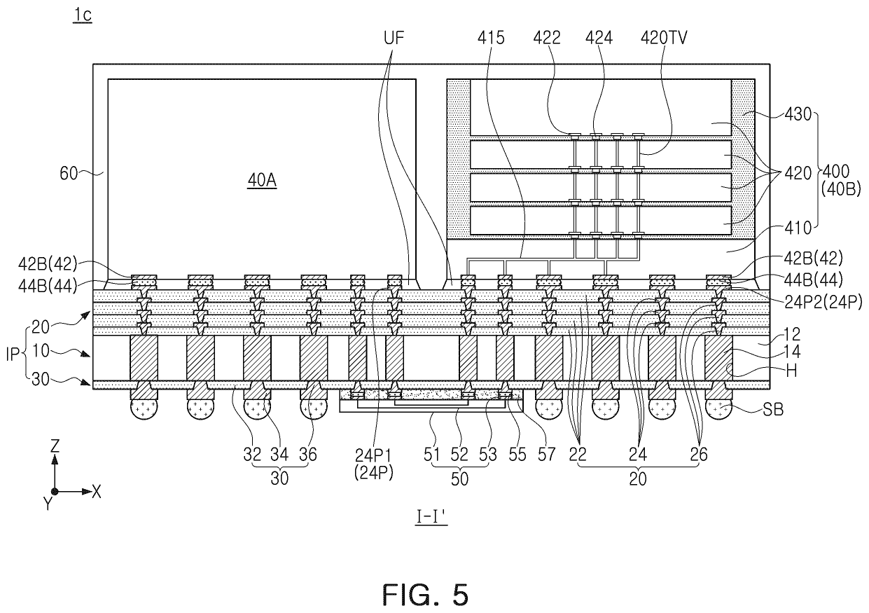

FIG. 5 is a vertical cross-sectional view of a semiconductor package 1c, according to some example embodiments. Referring to FIG. 5, the semiconductor package 1c may be same as or similar in some respects to the semiconductor packages described above with reference to FIGS. 1 to 4d, and therefore may be best understood with reference thereto where like numerals indicate like elements not described again in detail. In FIG. 5, the second chip structure 40B may be a high-capacity memory device 400. According to some example embodiments, an underfill layer UF may be formed below the first chip structure 40A and the second chip structure 40B. The underfill layer UF may be formed in the form of a capillary underfill (CUF) or a molded underfill (MUF).

In some example embodiments, the first chip structure 40A may be a logic chip including an ASIC, etc., and the second chip structure 40B may include a high-capacity memory device 400 including a plurality of memory chips 420, for example, a high bandwidth memory (HBM) or an electro data processing (EDP) device. For example, the memory device 400 may include a base chip 410, a memory chip 420, and/or a molding layer 430.

The base chip 410 may be a buffer chip or a control chip including a plurality of logic devices and/or memory devices. The base chip 410 may transmit signals from the memory chips 420 externally and may also transmit signals and power from an external source to the memory chips 420.

The memory chips 420 may be memory chips including volatile memory devices, such as DRAM and SRAM, or nonvolatile memory devices, such as PRAM, MRAM, FeRAM, RRAM, and flash memory. The memory chips 420 may be electrically connected to each other through a through-electrode 420TV. However, the uppermost memory chip 420 may not have the through-electrode 420TV and may have a relatively greater thickness than the rest of the memory chips 420. The memory chips 420 may include chip pads 422 disposed on lower surface thereof, respectively. Connection terminals 424 electrically connected to the chip pads 422 may be located between the adjacent memory chips 420.

The molding layer 430 may be disposed on the base chip 410 and may encapsulate at least a portion of each of the memory chips 420. The molding layer 430 may expose the upper surface of the uppermost memory chip 420. The molding layer 430 may be formed using, for example, EMC, but the material of the molding layer 430 is not limited thereto.

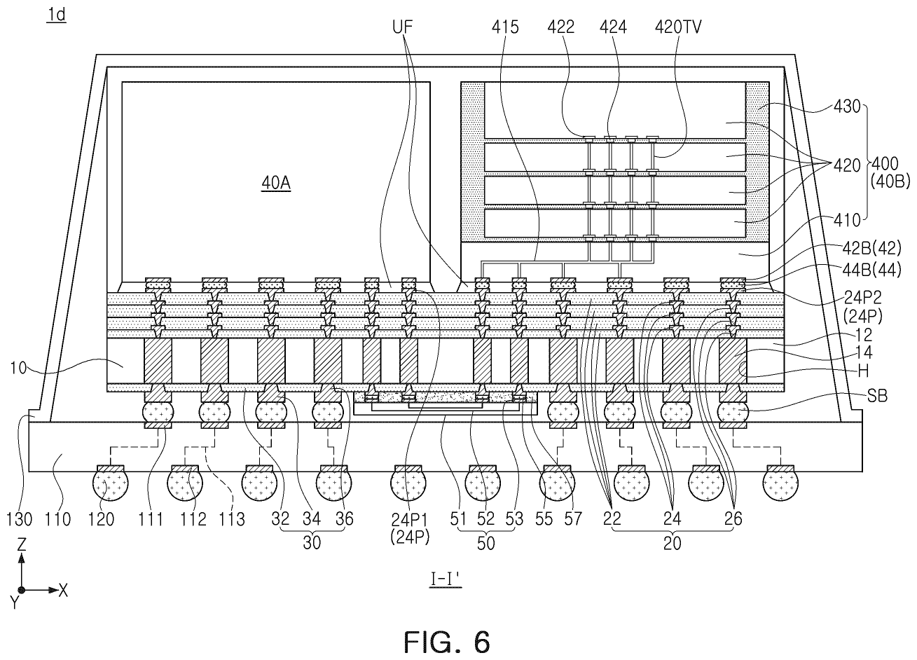

FIG. 6 is a vertical cross-sectional view of a semiconductor package 1d, according to some example embodiments. Referring to FIG. 6, the semiconductor package 1d may be same as or similar in some respects to the semiconductor packages described above with reference to FIGS. 1 to 5, and therefore may be best understood with reference thereto where like numerals indicate like elements not described again in detail. In FIG. 6, the semiconductor package 1d includes a base substrate 110 and a heat dissipation structure 130.

The semiconductor package 1d, according to some example embodiments, may include the base substrate 110, the interposer structure IP, and/or the chip structures 40A and 40B.

The base substrate 110 may be a support substrate on which the interposer structure IP may be mounted and may be a semiconductor package substrate, such as a printed circuit board (PCB), a ceramic substrate, or a tape wiring board. The base substrate 110 may include a lower pad 112 disposed on a lower surface thereof, an upper pad 111 disposed on an upper surface thereof opposite the lower surface, and an interconnection circuit 113 electrically connecting the lower pad 112 to the upper pad 111. The body of the base substrate 110 may include different materials depending on the type of the substrate. For example, the base substrate 110 may be a printed circuit board, and the base substrate 110 may be in the form in which an interconnection layer is additionally stacked on one surface or both surfaces of a body copper-clad laminate or a copper-clad laminate. An external connection terminal 120 connected to the lower pad 112 may be disposed on the lower surface of the base substrate 110. The external connection terminal 120 may include tin (Sn), indium (In), bismuth (Bi), antimony (Sb), copper (Cu), silver (Ag), zinc (Zn), lead (Pb), and/or alloys thereof.

The heat dissipation structure 130 may be disposed on the upper surface of the base substrate 110 and may be formed to cover the upper portions of the chip structures 40A and 40B. The heat dissipation structure 130 may be attached to the base substrate 110 by an adhesive. The adhesive may be a thermally conductive adhesive tape, a thermally conductive grease, a thermally conductive adhesive, or the like. A thermal interface material layer may be disposed between the heat dissipation structure 130 and the chip structures 40A and 40B. The heat dissipation structure 130 may include a material having relatively higher thermal conductivity, for example, a metal including gold (Au), silver (Ag), copper (Cu), iron (Fe), or metal alloy, or a material, such as graphite or graphene. The shape of the heat dissipation structure 130 may not be limited to the shape illustrated in FIG. 6. For example, the heat dissipation structure 130 may be plate shaped and may cover the upper surfaces of the chip structures 40A and 40B and may not cover the side surfaces of the chip structures 40A and 40B.

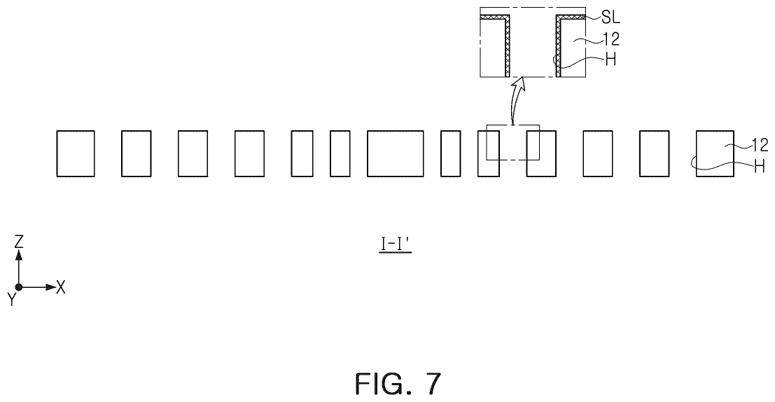

FIGS. 7 to 11 are views illustrating a method of manufacturing a semiconductor package, according to some example embodiments.

Referring to FIG. 7, the through-holes H may be formed in the glass core 12. A seed layer SL may be formed on the surface of the glass core 12. The seed layer SL may be formed on the upper surface and lower surface of the glass core 12 and inner walls of the through-holes H. The seed layer SL may include a metallic material, such as copper (Cu).

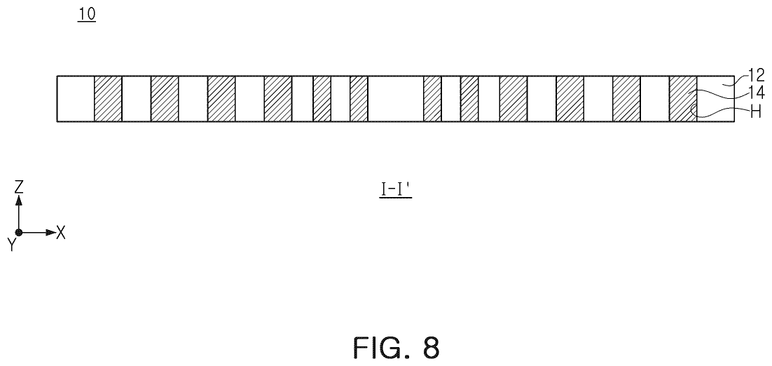

Referring to FIG. 8, the through-vias 14 may be formed in the through-holes H. For example, the through-vias 14 may be formed by a plating process using the seed layer SL as a seed. The metal layers may be formed by the plating process to fill the through-holes H and cover the upper and lower surfaces of the glass core 12. The through-vias 14 may be formed by performing a planarization process so that the metal layers are coplanar with the upper and lower surfaces of the glass core 12. The glass core 12 and the through-vias 14 may form a glass substrate 10.

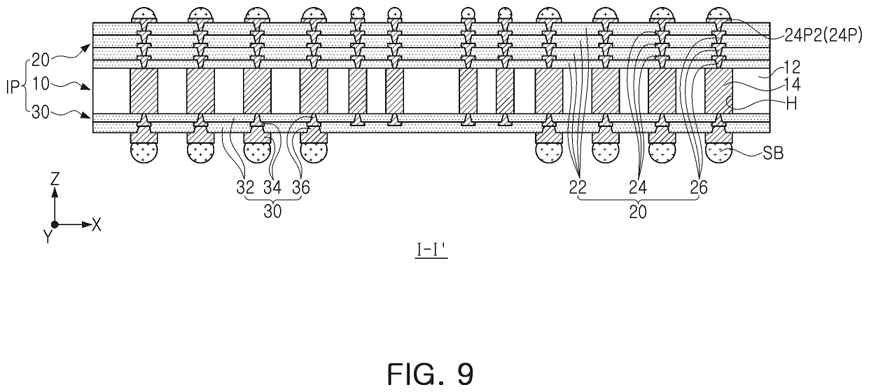

Referring to FIG. 9, the upper redistribution structure 20 may be formed on the glass substrate 10, and the lower redistribution structure 30 may be formed below the glass substrate 10. The upper redistribution structure 20 may include the upper insulating layer 22, the upper redistribution layer 24, and the upper redistribution via 26. The upper insulating layer 22 may be formed by applying and curing a photosensitive resin, such as PID, on the glass substrate 10. The upper redistribution layer 24 and the upper redistribution via 26 may be formed using a photolithography process, a plating process, or the like.

The lower redistribution structure 30 may include the lower insulating layer 32, the lower redistribution layer 34, and the lower redistribution via 36. The lower insulating layer 32 may be formed by applying and curing a photosensitive resin, such as PID, on the lower surface of the glass substrate 10. The lower redistribution layer 34 and the lower redistribution via 36 may be formed using a photolithography process, a plating process, or the like. In some example embodiments, the lower redistribution structure 30 may include a plurality of lower insulating layers 32 (2 layers shown in FIG. 9), that are vertically stacked, a plurality of lower redistribution layers 34 (2 layers shown in FIG. 9), and a plurality of lower redistribution vias 36 (2 vias shown in FIG. 9) connecting the plurality of lower redistribution layers 34. In some example embodiments, the lower redistribution structure 30 may be formed before the upper redistribution structure 20.

The solder bump SB connected to the lower redistribution layer 34 may be formed below the lower redistribution structure 30.

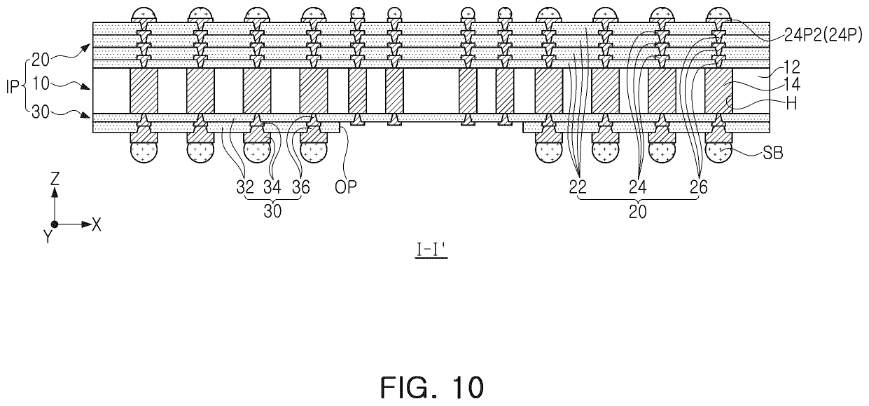

Referring to FIG. 10, the opening OP (or recess) may be formed by etching the lower insulating layer 32 of the lower redistribution structure 30. In some example embodiments, the opening OP may be formed by etching the lowermost lower insulating layer 32 among the plurality of lower insulating layers 32.

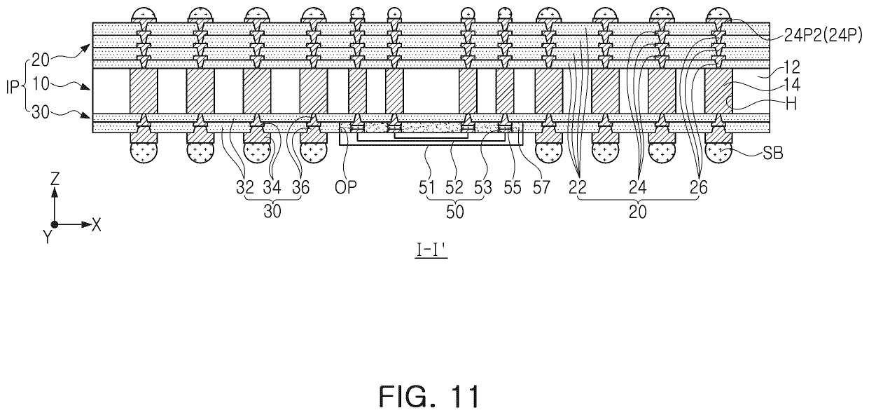

Referring to FIG. 11, the interconnection chip 50 may be mounted in the opening OP in a flip-chip manner. In some example embodiments, the interconnection pad 53 of the interconnection chip 50 may be connected to the lower redistribution layer 34 by the interconnection terminal 55, and the interconnection chip 50 may be attached to the lower redistribution structure 30 by the adhesive layer 57.

Referring to FIG. 4A and with continued reference to FIG. 11, the chip structures 40 (first chip structure 40A and second chip structure 40B) may be mounted on the upper redistribution structure 20 and the encapsulant 60 may be formed thereon, thereby manufacturing the semiconductor package 1b. The semiconductor package 1a described above with reference to FIGS. 1 to 3 may be manufactured by performing a process same as or similar to the process illustrated in FIGS. 7 to 9 and FIG. 11.

According to some example embodiments of the inventive concepts, the glass substrate has a relatively low coefficient of thermal expansion, and thus, warpage of the semiconductor package may be limited, inhibited, or minimized.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A semiconductor package comprising:
a glass substrate including a glass core and through-vias;
an upper redistribution structure including a plurality of upper redistribution layers on the glass substrate and electrically connected to the through-vias;
a first chip structure and a second chip structure on the upper redistribution structure and electrically connected to the upper redistribution structure;
an encapsulant at least partially covering the first chip structure and the second chip structure;
a lower redistribution structure below the glass substrate and including at least one lower redistribution layer electrically connected to the through-vias; and
an interconnection chip below the lower redistribution structure and electrically connecting the first chip structure to the second chip structure.

2. The semiconductor package of claim 1, wherein a coefficient of thermal expansion of the glass substrate is in a range of 8 ppm/K to 10 ppm/K.

3. The semiconductor package of claim 1, wherein a coefficient of thermal expansion of the glass substrate is less than a coefficient of thermal expansion of the upper redistribution structure and a coefficient of thermal expansion of the lower redistribution structure.

4. The semiconductor package of claim 1, wherein a horizontal width of the glass substrate is equal to a horizontal width of the encapsulant.

5. The semiconductor package of claim 1, wherein upper and lower surfaces of the through-vias are coplanar with upper and lower surfaces of the glass core, respectively.

6. The semiconductor package of claim 1, wherein a horizontal width of each of the through-vias is in a range of 1 μm to 200 μm.

7. The semiconductor package of claim 1, wherein a pitch of the through-vias is in a range of 10 μm to 100 μm.

8. The semiconductor package of claim 1, wherein the through-vias include first through-vias vertically overlapping the interconnection chip and second through-vias offset from the interconnection chip.

9. The semiconductor package of claim 8, wherein a horizontal width of each of the first through-vias is less than a horizontal width of each of the second through-vias.

10. The semiconductor package of claim 8, wherein a pitch of the first through-vias is less than a pitch of the second through-vias.

11. The semiconductor package of claim 8, wherein the upper redistribution structure includes upper redistribution vias electrically connecting the plurality of upper redistribution layers to the first through-vias, and a horizontal width of each of the upper redistribution vias is less than a horizontal width of each of the first through-vias.

12. The semiconductor package of claim 11, wherein a difference between the horizontal width of the upper redistribution vias and the horizontal width of the first through-vias is in a range of 5 μm to 50 μm.

13. The semiconductor package of claim 1, wherein a thickness of the glass substrate is in a range of 10 μm to 500 μm.

14. The semiconductor package of claim 1, further comprising:
a solder bump below the lower redistribution structure and electrically connected to the at least one lower redistribution layer,
wherein a lower surface of the interconnection chip is at a level higher than a lower end of the solder bump.

15. The semiconductor package of claim 1, wherein the lower redistribution structure includes a first lower insulating layer and a second lower insulating layer below the first lower insulating layer, the second lower insulating layer defines an opening, and the interconnection chip is within the opening.

16. The semiconductor package of claim 1, wherein the second chip structure includes a base chip mounted on the upper redistribution structure, a plurality of memory chips on the base chip, and a molding material covering the base chip and the plurality of memory chips.

17. A semiconductor package comprising:
an interposer structure;
a first chip structure and a second chip structure on the interposer structure;
an interconnection chip below the interposer structure and electrically connecting the first chip structure to the second chip structure; and
an adhesive layer between the interposer structure and the interconnection chip,
wherein the interposer structure includes,
a glass substrate including a glass core and through-vias;
an upper redistribution structure on the glass substrate and including a plurality of upper redistribution layers electrically connected to the through-vias; and
a lower redistribution structure below the glass substrate and including a plurality of lower redistribution layers electrically connected to the through-vias,
wherein a thickness of the upper redistribution structure is greater than a thickness of the lower redistribution structure.

18. The semiconductor package of claim 17, wherein
the plurality of lower redistribution layers include first lower redistribution layers electrically connected to the interconnection chip and second lower redistribution layers horizontally offset from the interconnection chip, and
the adhesive layer covers the first lower redistribution layers and an interconnection pad of the interconnection chip.

19. The semiconductor package of claim 18, wherein a pitch of the first lower redistribution layers is less than a pitch of the second lower redistribution layers.

20. A semiconductor package comprising:
a glass substrate including a glass core and through-vias;
an upper redistribution structure on the glass substrate and including upper redistribution layers electrically connected to the through-vias and upper redistribution vias connecting the upper redistribution layers;
a first chip structure and a second chip structure on the upper redistribution structure and electrically connected to the upper redistribution structure;
an encapsulant at least partially covering the first chip structure and the second chip structure;
a lower redistribution structure below the glass substrate and including a plurality of lower redistribution layers electrically connected to the through-vias and lower redistribution vias connecting the plurality of lower redistribution layers;
an interconnection chip below the lower redistribution structure and electrically connecting the first chip structure to the second chip structure;
an interconnection terminal between the interconnection chip and the lower redistribution structure; and
an adhesive layer between the interconnection chip and the lower redistribution structure and at least partially covering the interconnection terminal.
